(19) United States
(12) Patent Application Publication
(10) Pub. No.: US 2026/0214869 A1
(43) Pub. Date: Jul. 23, 2026

(54) POWER CONVERTER HAVING A COOLING ARRANGEMENT

(71) Applicant: MAGNA Powertrain GmbH & Co KG, Lannach (AT)

(72) Inventors: Patrick Lamplmayr, St. Georgen (AT); Josef Schadauer, Wolfsbach (AT)

(21) Appl. No.: 19/139,490

(22) PCT Filed: Dec. 19, 2023
(86) PCT No.: PCT/EP2023/086545

§ 371 Date: Jun. 16, 2025

(30) Foreign Application Priority Data
Dec. 22, 2022 (DE) 10 2022 214 325.6

(51) Int. Cl. H05K 7/20; H05K 5/04

(52) U.S. Cl. CPC H05K 7/20927; H05K 5/04; H05K 7/209

(57) ABSTRACT

A power converter for converting one supplied power type into another power type includes a housing, with two housing parts that are connected together to form a cavity, at least one power module, and a cooling assembly. The power module and the cooling assembly are arranged in the cavity and are operatively connected together in a thermal manner. The cooling assembly has two cooling bodies and two frame parts, and the power module is sandwiched between the two cooling bodies. Each cooling body is inserted into a respective frame part, and the frame parts with the inserted cooling body are held in a respective housing part, which are connected together via multiple tubular rivets.

### CROSS-REFERENCE TO RELATED APPLICATIONS

This application is a National Stage of International Application No. PCT/EP2023/086545, filed Dec. 19, 2023, which claims priority to DE 10 2022 214 325.6, filed Dec. 22, 2022. The entire disclosures of each of the above applications are incorporated herein by reference.

### FIELD

The present disclosure relates to a power converter for converting one type of supplied current into another, including a housing, which has two housing parts that are connected to each other in such a way that they define a cavity in the housing, at least one power module and a cooling arrangement, wherein the power module and the cooling arrangement are arranged in the cavity of the housing and are thermally operatively connected to each other.

### BACKGROUND

This section provides information related to the present disclosure which is not necessarily prior art.

Power converters are power electronic circuits for converting electrical energy. By way of power converters, alternating current may be converted into direct current (rectifier), direct current into alternating current (inverter), alternating current into alternating current of a different frequency and/or amplitude, or direct current into direct current of a different voltage (converter).

A power converter includes at least one power module, such as a semiconductor switch, namely, for example, a MOSFET (metal-oxide semiconductor field-effect transistor), an IGBT (insulated-gate bipolar transistor) or similar.

Particularly in the case of high-performance applications of a power converter such as, for example, as an inverter in a hybrid or electric vehicle, a considerable amount of waste heat is produced as a result of switching and conduction losses in the power module of the power converter. This waste heat must be removed in order to ensure fault-free functioning of the power module, and thus of the power converter. Accordingly, a cooling arrangement is usually provided, which serves to cool the power module of the power converter as required. Such a cooling arrangement may be realized, for example, by thermally connecting the power module to a heatsink through which a liquid is circulated, or by allowing air to flow over the power module.

Depending on the area of application and conceptual peculiarities in the respective application (stability, quantity of waste heat, installation space, costs, etc.), it is necessary to customize the power converter design, in particular the design of the cooling arrangement.

### SUMMARY

This section provides a general summary of the disclosure, and is not a comprehensive disclosure of its full scope or all of its features.

It is an object of the present disclosure to provide a power converter, having a cooling arrangement, having an improved structure.

This object is met by the subject-matter of the present disclosure and the aspects and embodiments described herein. In the following, features, details and possible advantages of a device according to embodiments of the present disclosure are discussed in detail.

The power converter according to the present disclosure serves to convert one type of supplied current into another, and includes a housing, at least one power module, and a cooling arrangement.

According to the present disclosure, the housing includes two housing parts that are connected to each other in such a way that they define a cavity in the housing.

The power module usually includes an interconnection of a plurality of semiconductor switches that is suitable for effecting clocking for the purpose of converting the one type of supplied current into another type. The interconnection may be, for example, a half-bridge or full-bridge circuit, the semiconductor switches typically being MOSFETs or IGBTs of a common semiconductor material such as, for example, silicon.

According to the present disclosure, the power module and the cooling arrangement are arranged in the cavity of the housing and are thermally operatively connected to each other.

According to the present disclosure, the cooling arrangement has at least two heatsinks and at least two frame parts, wherein the power module is arranged in a flat manner between the two heatsinks, such that a sandwich-type arrangement of the heatsink-power module-heatsink configuration is realized.

According to the present disclosure, there is respectively at least one heatsink inserted into respectively one frame part, and the frame parts, with inserted heatsink, are each respectively held in a housing part of the housing.

According to the present disclosure, the two housing parts are connected to each other via a plurality of tubular rivets. The central openings of the tubular rivets may further be used as screw points for mounting the power converter according to the present disclosure to another component. This creates a simple, space-saving way of fastening the power converter.

The housing parts are preferably produced from a metallic material such as, for example, high-grade steel.

The frame parts are preferably produced from a polymer material. The frame parts serve to position, align and hold the heatsinks in place.

The heatsinks are preferably produced from a metallic material such as, for example, aluminum or copper.

In a preferred embodiment variant of the present disclosure, there is a coolant inlet realized in one housing part, and a coolant outlet in the other housing part. However, a different design and integration of the coolant inlet and the coolant outlet is also conceivable. Thus, for example, it is conceivable for a tubular coolant inlet and a tubular coolant outlet to be realized integrally with a frame part, and for these to be routed out of the housing cavity to the environment of the housing via suitable recesses, or openings, in the housing.

The modular structure of the power converter, in particular of the cooling arrangement of the power converter, allows the materials to be adapted as required, individually and cost-effectively. Each component may be produced according to requirement and demand, using a favorable production process and favorable material.

Because there is no material bond between the individual parts of the power converter, a high degree of flexibility is achieved in replacing the individual parts, and the structure of the power converter may be adapted according to parameters such as the amount of heat to be removed, permitted pressure loss, installation space, costs, maximum temperature, etc.

Furthermore, due to the multiple use of parts and assemblies, development and component costs can be minimized.

### BRIEF DESCRIPTION OF THE DRAWINGS

The drawings described herein are for illustrative purposes only of selected embodiments and not all possible implementations, and are not intended to limit the scope of the present disclosure.

An example of the present disclosure is described below with reference to the drawings.

FIG. 1 shows a perspective view of a power converter.

FIG. 2 shows a top view of a power converter.

FIG. 3 shows a first sectional representation of a power converter.

FIG. 4 shows a second sectional representation of a power converter.

FIG. 5 shows an exploded representation of a power converter.

### DETAILED DESCRIPTION

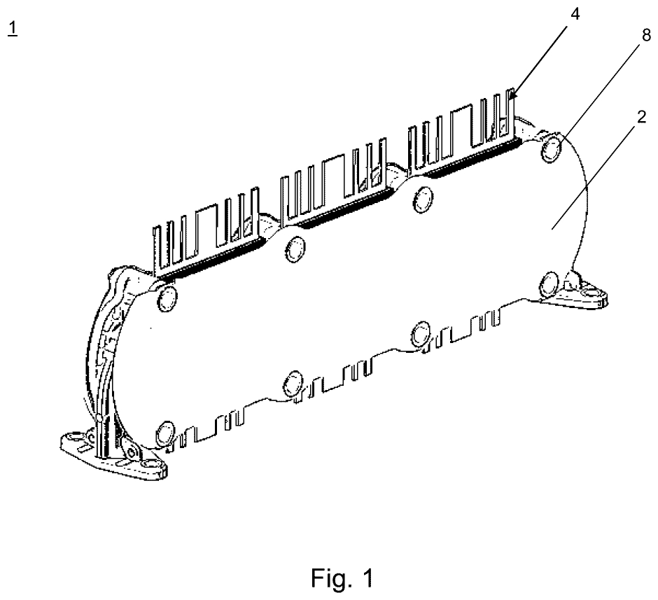

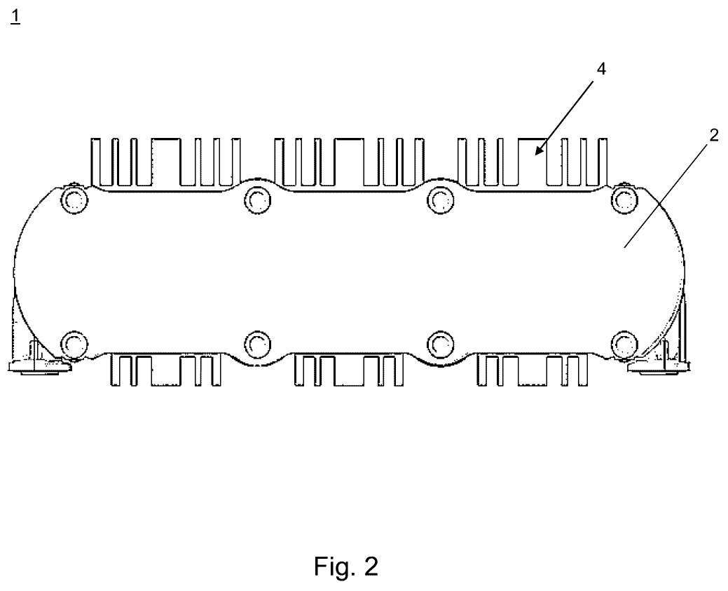

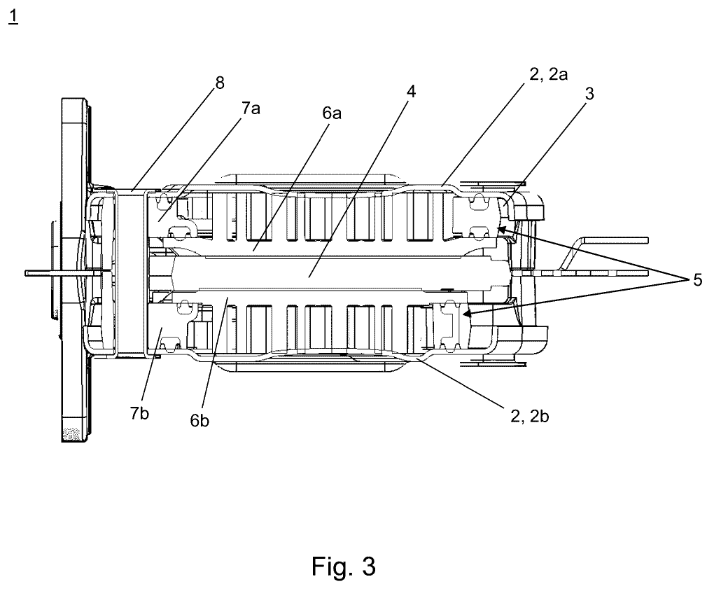

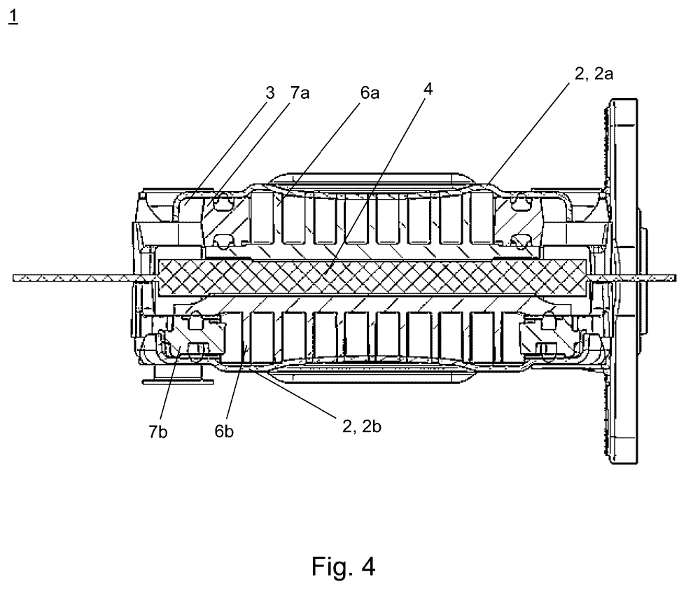

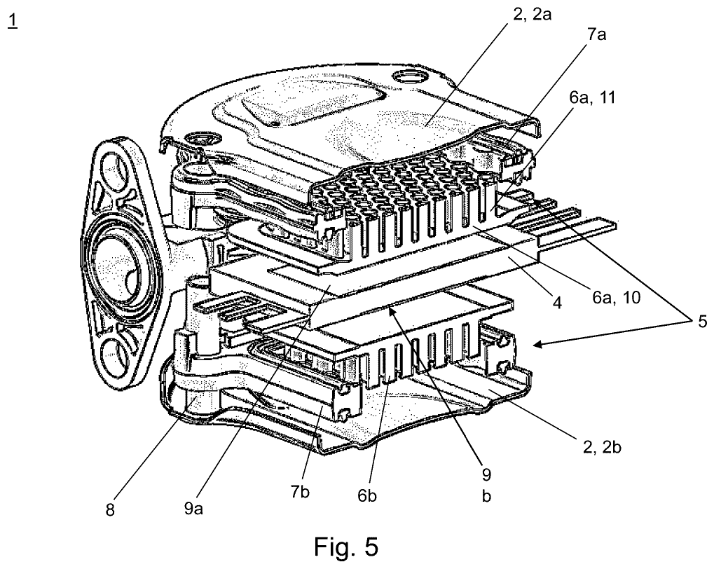

An example of a power converter 1 according to the present disclosure is represented, in different representation variants, in FIG. 1 to FIG. 5.

The power converter 1 includes a housing 2, three power modules 4, and a cooling arrangement 5.

The housing has two housing parts 2a, 2b, which are connected to each other in such a way that they define a cavity 3 in the housing 2.

The power modules 4 and the cooling arrangement 5 are arranged in the cavity 3 of the housing 2 and are thermally operatively connected to each other.

The cooling arrangement 5 has two heatsinks 6a, 6b and at least two frame parts 7a, 7b, the power module 4 being arranged in a flat manner between the two heatsinks 6a, 6b, such that a sandwich-type arrangement of the heatsink 6a—power module 4—heatsink 6b configuration is realized.

There is respectively one heatsink 6a, 6b inserted into respectively one frame part 7a, 7b. The frame parts 7a, 7b, with the respectively inserted heatsinks 6a, 6b, are each held in a housing part 2a, 2b of the housing 2.

The two housing parts 2a, 2b are connected to each other via a plurality of tubular rivets 8.

A respective power module 4 has two silicon carbide MOSFETs as semiconductor switches in a half-bridge circuit (not represented). The two semiconductor switches are fixed on a carrier plate (not represented), which is thermally operatively connected to two waste-heat surfaces 9a, 9b. The two waste-heat surfaces 9a, 9b are located on the outer surfaces of the power module 4, on two opposite sides of the power module 4. Fixed to each of these waste-heat surfaces 9a, 9b there is a respective heatsink 6a, 6b of the cooling arrangement 5. There is a heat-conducting paste applied between the respective heatsink 6a, 6b and the respective waste heat surface 9a, 9b for improved heat transfer of the waste heat from the power module 4 into the respective heatsink 6a, 6b.

The heatsinks 6a, 6b each have a base plate 10 having a multiplicity of pins 11, which project on one side from the base plate 10 (in the direction of the waste-heat surface 9a, 9b of the power module 4).

There is a coolant inlet realized in one housing part 2a, and a coolant outlet in the other housing part 2b.

By way of a frame part 7a, 7b, a heatsink 6a, 6b and a housing part 2a, 2b, there is a respective a cooling channel realized on both sides of the power module 4. The two cooling channels are fluidically connected to each other. The coolant in this case enters the cooling channels via the coolant inlet, and exits the cooling channels via the coolant outlet.

### LIST OF REFERENCE SIGNS

1 power converter
2 housing
2a, 2b housing parts
3 cavity
4 power module
5 cooling arrangement
6a, 6b heatsinks
7a, 7b frame parts
8 tubular rivets
9a, 9b waste-heat surfaces
10 base plate
11 pin

1. A power converter for converting one type of supplied current into another, comprising
a housing, which has two housing parts that are connected to each other in such a way that they define a cavity in the housing,
at least one power module, and
a cooling arrangement,
wherein the power module and the cooling arrangement are arranged in the cavity of the housing and are thermally operatively connected to each other,
wherein the cooling arrangement includes at least two heatsinks and at least two frame parts,
wherein the power module is arranged in a flat manner between the two heatsinks, such that a sandwich-type arrangement of the heatsink—power module—heatsink configuration is defined,
wherein there is respectively at least one heatsink (6a, 6b) inserted into respectively one frame part (7a, 7b), and
wherein the frame parts (7a, 7b), with inserted heatsink (6a, 6b), are each respectively held in one of the housing parts (2a, 2b) of the housing (2), and
wherein the two housing parts (2a, 2b) are connected to each other via a plurality of tubular rivets (8).

2. The power converter (1) as claimed in claim 1,
wherein the housing parts (2a, 2b) are produced from a metallic material.

3. The power converter (1) as claimed in claim 2,
wherein the housing parts (2a, 2b) are produced from high-grade steel.

4. The power converter (1) as claimed in claim 2,
wherein the frame parts (7a, 7b) are produced from a polymer material.

5. The power converter (1) as claimed in claim 4,
wherein the heatsinks (6a, 6b) are produced from a metallic material.

6. The power converter (1) as claimed in claim 5,
wherein the heatsinks (6a, 6b) are produced from aluminum or copper.

7. The power converter as claimed in claim 1,
wherein a coolant inlet is defined in one housing part (2a), and a coolant outlet is defined in the other housing part (2b).

8. The power converter as claimed in claim 1, wherein the tubular rivets defined screw points for mounting the power converter.

9. The power converter as claimed in claim 1, wherein the frame parts position, align, and hold the heatsinks in place

10. The power converter as claimed in claim 1, wherein there is no material bond between the power module and heatsinks and frame parts.

11. The power converter as claimed in claim 1, wherein multiple power modules are sandwiched between one pair of heatsinks.

12. The power converter as claimed in claim 1, wherein the frame parts, heatsinks, and housing parts combine to define two cooling channels, with the two cooling channels disposed on each side of the power module.

13. The power converter as claimed in claim 1, wherein the two cooling channels are fluidically connected to each other.
